(19) United States
(12) Patent Application Publication
(10) Pub. No.: US 2015/0004546 A1
(43) Pub. Date: Jan. 1, 2015

(54) METHOD FOR FABRICATING PHOTO SPACER

(71) Applicant: Wistron Corporation, New Taipei City (TW)

(72) Inventors: Yi-Kai Wang, New Taipei City (TW); Tarng-Shiang Hu, New Taipei City (TW); Tsung-Hua Yang, New Taipei City (TW); Yu-Jung Peng, New Taipei City (TW); Chih-Hao Chang, New Taipei City (TW)

(21) Appl. No.: 14/487,102

(22) Filed: Sep. 16, 2014

Related U.S. Application Data
(62) Division of application No. 13/312,994, filed on Dec. 7, 2011.

(30) Foreign Application Priority Data
Sep. 29, 2011 (TW) 100135290

(51) Int. Cl. G03F 7/40; G03F 7/20

(52) U.S. Cl. CPC G03F 7/40; G03F 7/20
USPC 430/321

(57) ABSTRACT

A method for fabricating a photo spacer and an array substrate having the photo spacer are provided. At least one exposure process, a developing process, and a baking process are performed to a photo-sensitive material layer formed a substrate to fabricate a photo spacer, wherein the at least one exposure process includes a back side exposure process. The substrate has a light transmitting region and a light shielding region so that the photo-sensitive material layer is defined into a first block and a second block after the back side exposure process. The developing process is performed to at least remove the second block. A front side exposure process is performed to the first block. The baking process is performed to cure the first block of the photo-sensitive material layer to form a photo spacer.

### CROSS-REFERENCE TO RELATED APPLICATION

This application is a divisional of and claims the priority benefit of U.S. patent application Ser. No. 13/312,994, filed on Dec. 7, 2011, now pending, which claims the priority benefit of Taiwan application serial no. 100135290, filed on Sep. 29, 2011. The entirety of each of the above-mentioned patent applications is hereby incorporated by reference herein and made a part of this specification.

### BACKGROUND OF THE INVENTION

1. Field of the Invention

The disclosure relates to methods for fabricating a spacer and an array substrate. Particularly, the disclosure relates to methods for fabricating a photo spacer and an array substrate having the photo spacer.

2. Description of Related Art

An electrophoretic display can be applied to flexible electronic products such as electronic books, etc. However, a biggest drawback of the electrophoretic display is that it does not have a good colorizing technique, and cannot meet consumer's demand regardless of using color filters or in new technique development.

Although a conventional liquid crystal display (LCD) has a good colorizing property, when it is applied to the flexible electronic product, since a flexible substrate is required, a problem of substrate deformation caused by a process temperature during the fabrication process has to be considered. Moreover, after an active device array is fabricated on the flexible substrate, how to assemble the flexible active device array substrate and a counter substrate to maintain ideal alignment accuracy is another problem required to be resolved.

Taking a design of the LCD as an example, fabrication and configuration of a spacer greatly influence a display effect. The conventional glass spacer is randomly configured inside the display, and the glass spacer is not fixed on any of the substrates, so that it is not suitable for flexible display fabrication. A photo spacer can be fabricated and fixed on a substrate through a conventional photolithography process. However, to fabricate the photo spacer on the flexible substrate, a problem of substrate deformation due to previous fabrication steps has to be considered, and in case of a severe deformation, the photo spacer is probably dislocated, which may have a negative influence on the display effect of the display.

Therefore, to meet the requirements of today's electronic products, flexibility of the LCD and none dislocation of the spacer inside the display are required to be achieved.

### SUMMARY OF THE INVENTION

The disclosure is directed to a method for fabricating a photo spacer, by which the photo spacer is fabricated in a self-alignment manner to avoid dislocation of the photo spacer.

The disclosure is directed to a method for fabricating a photo spacer, by which the photo spacer is defined in a self-alignment manner, and such method has a higher tolerance for an alignment error.

The disclosure is directed to an array substrate, on which a photo spacer is aligned to a light shielding device to avoid a problem of mis-alignment.

The disclosure provides a method for fabricating a photo spacer. A photo-sensitive material layer is formed on a substrate, where the substrate has at least one light shielding region and at least one light transmitting region. At least one exposure process is performed to the photo-sensitive material layer, and the at least one exposure process includes a back side exposure process, where light irradiates the photo-sensitive material layer from a side of the substrate apart from the photo-sensitive material layer to define at least one first block located on the at least one light shielding region and at least one second block located on the at least one light transmitting region in the photo-sensitive material layer. A developing process is performed to at least remove the second block. A front side exposure process is performed to the at least one first block. A baking process is performed to cure the first block of the photo-sensitive material layer to form a photo spacer.

The disclosure provides a method for fabricating a photo spacer. A photo-sensitive material layer is formed on a substrate, where the substrate has at least one light shielding region and at least one light transmitting region, and the photo-sensitive material layer includes at least one first block located on the at least one light shielding region and at least one second block located on the at least one light transmitting region. A back side exposure process is performed, and light irradiates the photo-sensitive material layer from the substrate to expose the at least one second block. A developing process is performed to remove the at least one second block from the substrate. A coking process is performed to cure the first block into at least one photo spacer, where a process temperature of the coking process is from 170° C. to 190° C.

The disclosure provides a method for fabricating a liquid crystal display. A photo-sensitive material layer is formed on a first substrate, where the first substrate has at least one light shielding region and at least one light transmitting region. At least one exposure process is performed to the photo-sensitive material layer, and the at least one exposure process includes a back side exposure process, and light irradiates the photo-sensitive material layer from a side of the first substrate apart from the photo-sensitive material layer to define at least one first block located on the at least one light shielding region and at least one second block located on the at least one light transmitting region in the photo-sensitive material layer. A developing process is performed to at least remove the second block. A front side exposure process is performed to the at least one first block. A baking process is performed to cure the first block of the photo-sensitive material layer to form a photo spacer. The first substrate formed with the photo spacer and a second substrate are assembled, and a liquid crystal layer is formed between the first substrate and the second substrate.

According to the above descriptions, the back side exposure process is performed to self-align the photo spacer and the light shielding device on the substrate, so as to avoid mis-alignment of the photo spacer. Moreover, in the fabrication process of the photo spacer, the back side exposure process can be used to first expose the photo-sensitive material layer, and then a mask is used to define the required pattern, and regardless whether alignment of the mask is accurate, the photo spacer can be indeed located on the light-shielding device. Therefore, the fabrication method of the disclosure has a relatively higher tolerance for the alignment error.

In order to make the aforementioned and other features and advantages of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a top view of an array substrate according to an embodiment of the disclosure.

FIGS. 2A-2E are schematic diagrams illustrating a fabrication method of a photo spacer according to a first embodiment of the disclosure.

FIG. 3 is a top view of another array substrate according to an embodiment of the disclosure.

FIGS. 4A-4F are schematic diagrams illustrating a fabrication method of a photo spacer according to a second embodiment of the disclosure.

FIGS. 5A-5F are schematic diagrams illustrating a fabrication method of a photo spacer according to a third embodiment of the disclosure.

FIGS. 6A-6B are schematic diagrams illustrating a fabrication method of a photo spacer according to a fourth embodiment of the disclosure.

FIGS. 7A-7C are schematic diagrams illustrating a fabrication method of a photo spacer according to a fifth embodiment of the disclosure.

### DETAILED DESCRIPTION OF DISCLOSED EMBODIMENTS

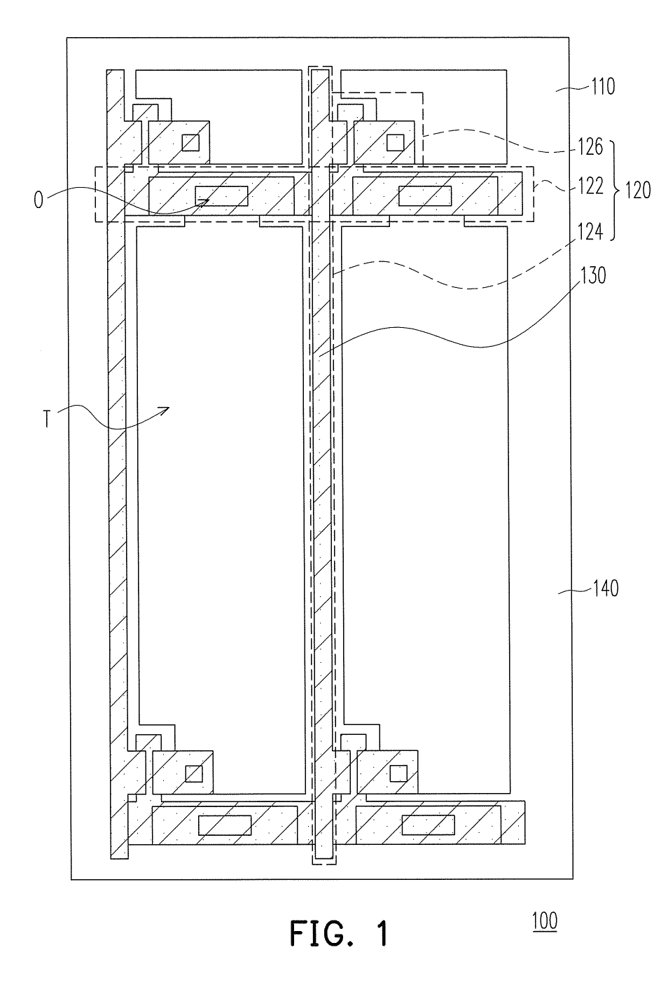

FIG. 1 is a top view of an array substrate according to an embodiment of the disclosure. Referring to FIG. 1, the array substrate 100 includes a substrate 110, at least one light-shielding device 120 which is disposed on the substrate 110 to divide the substrate 110 into at least one light transmitting region T and at least one light shielding region O, and a photo spacer 130 which is disposed on the substrate 110 and located in the light shielding region O. In the present embodiment, a profile of the photo spacer 130 is overlapped to a profile of the light shielding device 120, so that an area of the photo spacer 130 substantially covers an area of the light shielding device 120, though the disclosure is not limited thereto. Moreover, a material of the photo spacer 130 can be an image reversal photoresist, where the material of the photo spacer 130 includes AZ5214E, TI 35E, TI 35ES, TI Plating, TI xLift, TI Spray, AZ nLof 2070, though the disclosure is not limited thereto, and in an embodiment, the material of the photo spacer 130 can also be a positive photoresist.

The light shielding device 120 includes a scan line 122, a data line 124, and an active device 126. Moreover, the substrate 110 can be further configured with a plurality of pixel electrodes 140 in order to apply in a liquid crystal display (LCD). The pixel electrodes 140 are disposed on the substrate 110 and are at least located in the light transmitting region T, and the pixel electrode 140 is electrically connected to a corresponding scan line 122 and a corresponding data line 124 through an active device 126. The pixel electrode 140 can be overlapped to one of the scan lines 122 to form a storage capacitor, though the disclosure is not limited thereto.

In the present embodiment, a pattern formed by the photo spacer 130 can be self-aligned to the light shielding device 120 through an exposure process. In the light shielding device 120 of the present embodiment, the scan line 122 and the data line 124 are intersected to form a grid-like pattern, so that the photo spacer 130 formed by the self-aligned exposure process substantially has the same grid-like pattern. In this way, when the array substrate 100 is applied to the LCD, the photo spacer 130 is indeed distributed in the light shielding region O, which avails improving display quality of the LCD by configuring the photo spacer 130 overlapping the light shielding devices 120.

Moreover, since the photo spacer 130 can be self-aligned to the light shielding device 120 during the fabrication process, regardless whether the substrate 110 is a flexible substrate or a non-flexible rigid substrate, the position of the photo spacer 130 falls in the light shielding region O. Therefore, the misalignment between the photo spacer 130 and the light shielding devices 120 can be prevented and thus the material of the substrate is not limited to be flexible or non-flexible, so as to achieve a wider application range. Namely, the array substrate 100 of the present embodiment can be applied to a flexible product.

In detail, in order to further describe characteristics of the photo spacer of the present embodiment, a fabrication process of the photo spacer is described below.

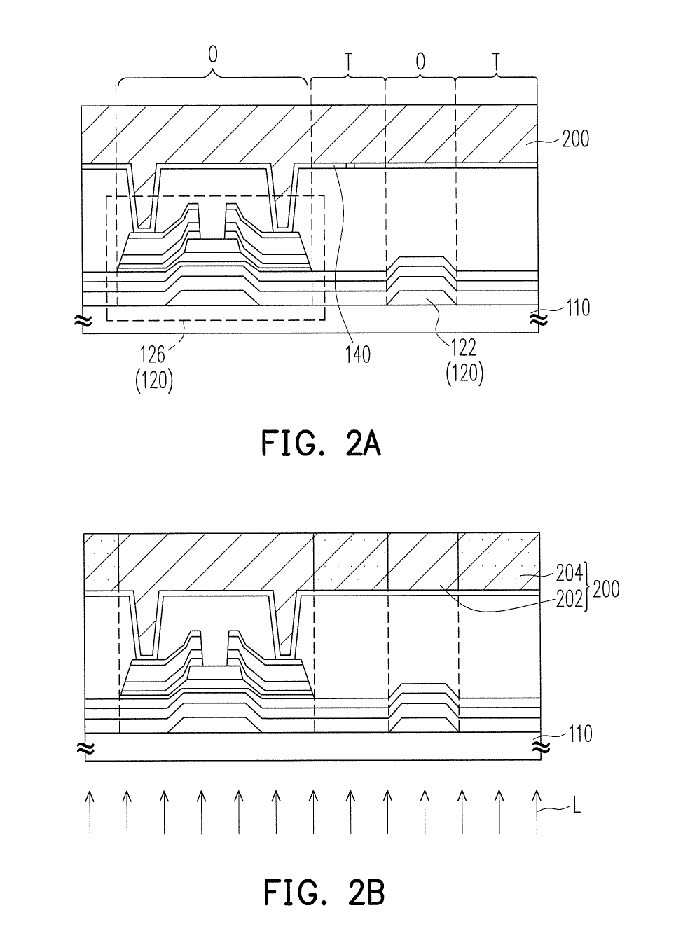

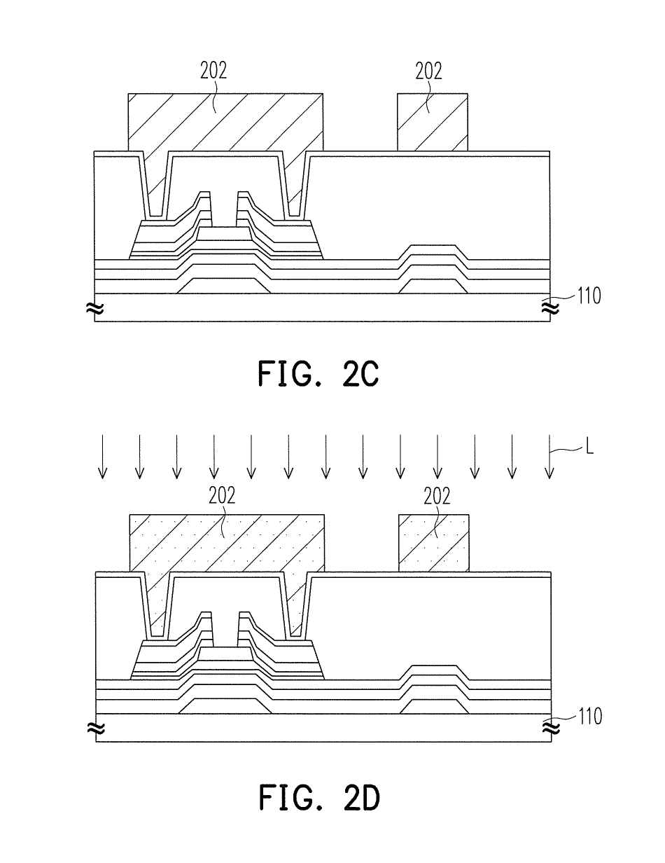

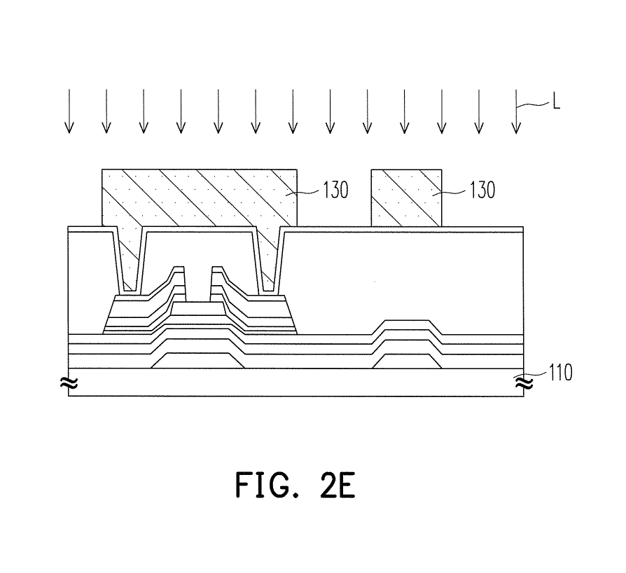

FIGS. 2A-2E are schematic diagrams illustrating a fabrication method of a photo spacer according to a first embodiment of the disclosure. Referring to FIG. 2A, a photo-sensitive material layer 200 is formed on the substrate 110. Here, the light shielding device 120 shown in FIG. 1 has been formed on the substrate 110, so that the regions on the substrate 110 configured with the light shielding device 120 are the light shielding regions O, and the other regions are the light transmitting regions T. The photo-sensitive material layer 200 has a feature of presenting in a decomposed state after exposure.

Then, referring to FIG. 2B, a back side exposure process is performed, and light L irradiates the photo-sensitive material layer 200 from a side of the substrate 110 apart from the photo-sensitive material layer 200. Now, the photo-sensitive material layer 200 is divided into at least one first block 202 located on the light shielding region O and at least one second block 204 located on the light transmitting region T. Since the light shielding device 120 shields a part of the light L, only the second block 204 is exposed during the back side exposure process. Therefore, the second block 204 is in the decomposed state.

Next, referring to FIG. 2B and FIG. 2C, a developing process is performed, by which a developer is used to remove the second blocks 204 presenting in the decomposed state from the substrate 110. Now, the first blocks 202 are not exposed, so that the first blocks 202 are not dissolved in the developer, and are still remained on the substrate 110.

Thereafter, referring to FIG. 2D and FIG. 2E, a front side exposure process is performed to expose the first blocks 202, and then a baking process is performed to cure the first blocks 202 to form the photo spacer 130 shown in FIG. 1. A baking temperature of the baking process is, for example, 110° C. to 130° C.

In detail, the photo-sensitive material layer 200 of the present embodiment is, for example, composed of the image reversal photoresist material, and according to a characteristic of such type of material, after being exposed and baked, the photo-sensitive material layer 200 having a material of the image reversal photoresist is cured to form the photo spacer 130. In the present embodiment, a required pattern can be obtained by adjusting a progress sequence of the exposure process, so as to the required photo spacer 130.

Moreover, in the present embodiment, the back side exposure process is used to define a pattern of the photoresist material layer 200, so as to self-align the light shielding device 120 and the photo spacer 130. Therefore, the photo spacer 130 is substantially located in the light shielding region O only, so as to avoid mis-alignment of the photo spacer 130 when the array substrate 100 is applied to the LCD. In other words, ideal display quality is achieved when the array substrate 100 is applied to the LCD. Further, after the image reversal photoresist is cured, it is not liable to be deteriorated in subsequent processing steps or utilization process due to light irradiation, so that the photo spacer 130 fabricated according to the fabrication method of the present embodiment has ideal reliability.

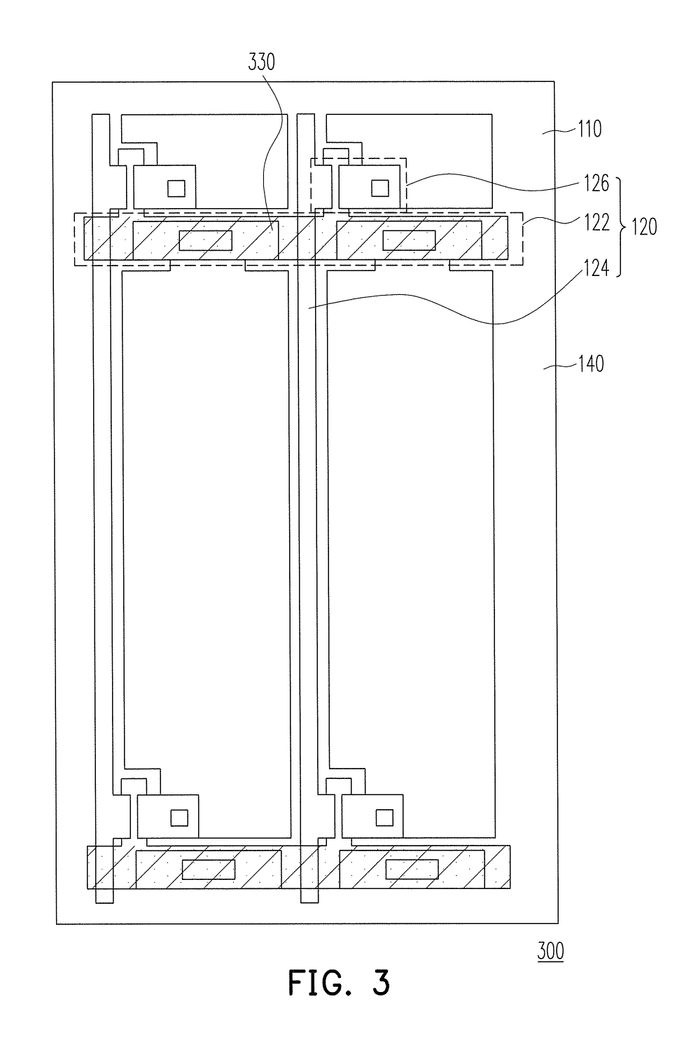

FIG. 3 is a top view of another array substrate according to an embodiment of the disclosure. Referring to FIG. 3, the array substrate 300 is similar to the array substrate 100 of the first embodiment, and a difference therebetween is that a photo spacer 330 of the present embodiment is approximately overlapped to the scan line 122 of the light shielding device 120, and is not completely overlapped to the data line 124. Namely, the photo spacer 330 on the array substrate 300 substantially forms a plurality of bar-shape patterns parallel to the scan line 122, which is different to the photo spacer 130 of the grid-like pattern of the first embodiment.

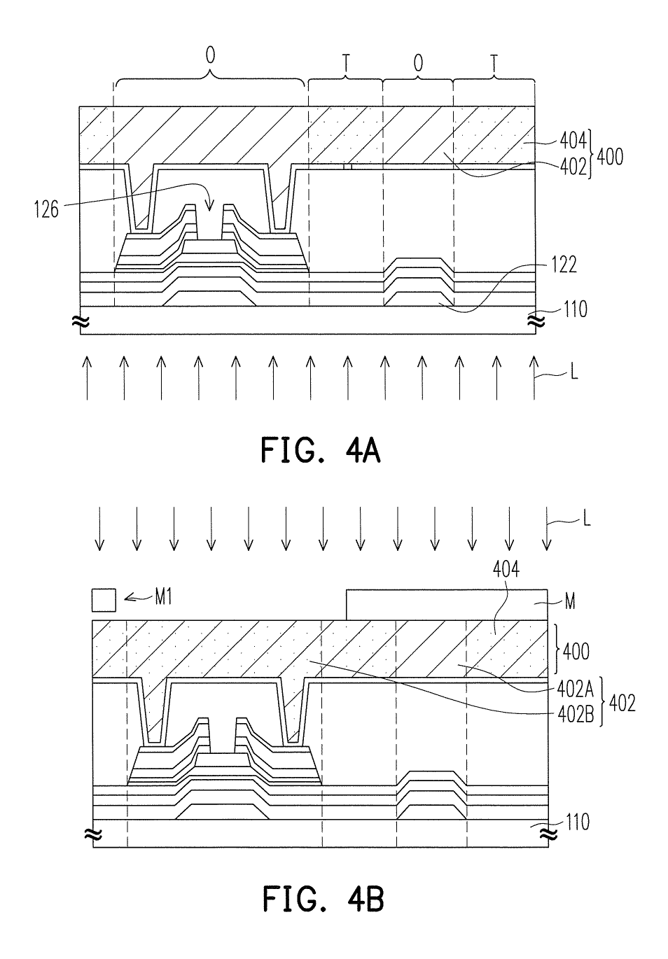

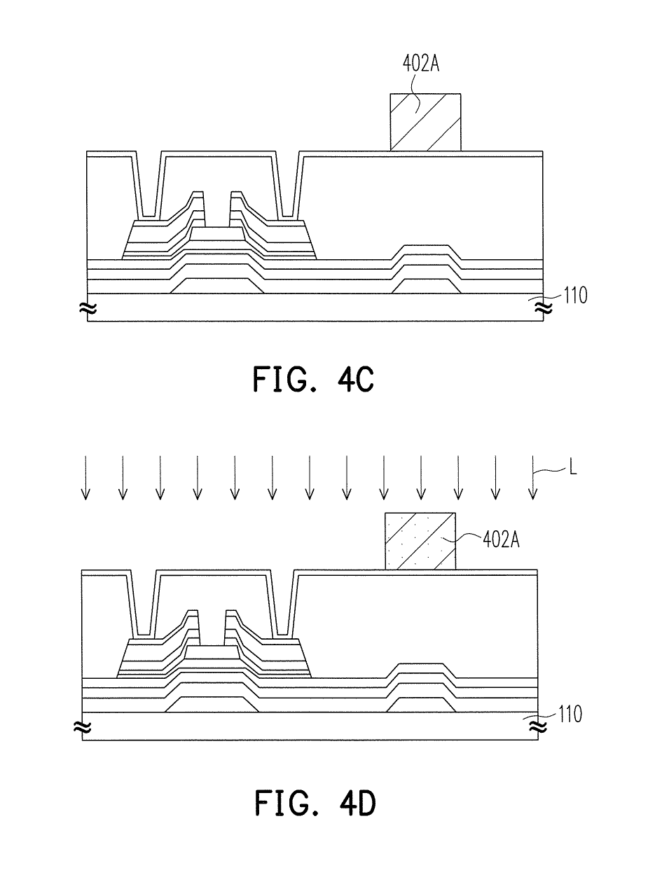

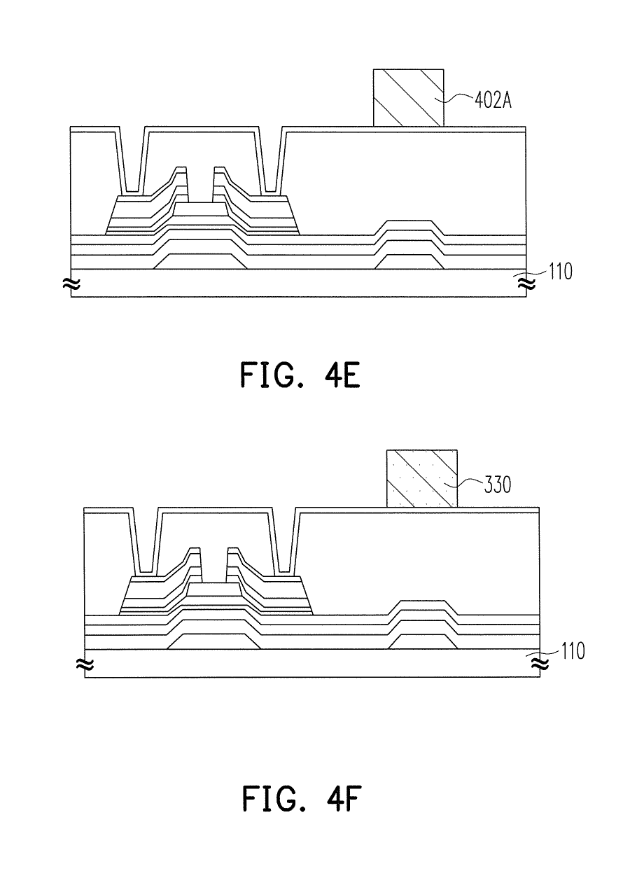

FIGS. 4A-4F are schematic diagrams illustrating a fabrication method of a photo spacer according to a second embodiment of the disclosure. Referring to FIG. 4A, a back side exposure process is performed on the substrate 110 formed with a photo-sensitive material layer 400. The back side exposure process is the same to that of the first embodiment, so that after the light irradiation, the photo-sensitive material layer 400 is defined into a first block 402 and a second block 404, where the first block 402 is located in the light shielding region O and the second blocks 404 is located in the light transmitting region T. Meanwhile, the photo-sensitive material layer 400 has a first light-sensitive property and is decomposed after exposure. In other word, the second block 404 is in the decomposed state.

Then, referring to FIG. 4B, a partial exposure process is performed, and the light L irradiates the light-sensitive material layer 400 from a side of the light-sensitive material layer 400 apart from the substrate 110 through a mask M. The mask M has an opening M1 so as to shield a first sub block 402A of the first block 402 and expose a second sub block 402B of the first block 402 through the opening M1. Now, the second block 404 and the second sub block 402B are exposed, so that the second block 404 and the second sub block 402B are in the decomposed state.

Then, referring to FIG. 4C, a developing process is performed to remove the second block 404 and the second sub block 402B presenting the decomposed state from the substrate 110. In overall, after the back side exposure process and the partial exposure process, only the first sub block 402A of the photo-sensitive material layer 400 located in the light shielding region O is not exposed, so that the first sub block 202 is still remained on the substrate 110 after the developing process.

Thereafter, referring to FIG. 4D, a front side exposure process is performed, and the light L irradiates a side of the substrate 110 configured with the first sub block 402A to expose the first sub block 402A. Now, the first sub block 402A is in the decomposed state due to exposure.

Then, referring to FIG. 4E, a baking process is performed to cure the exposed first sub block 402A to form the photo spacer 330. A baking temperature of the baking process is, for example, 110° C. to 130° C.

In the present embodiment, a specific pattern of the first block 402 located on the light shielding region O can be defined through the partial exposure process. Therefore, in the array substrate 300, the photo spacer 330 is not required to have the same pattern as that of the light shielding device 120. In this way, when the array substrate 300 is applied to the LCD, a distribution density of the photo spacer 330 can be changed according to different utilization requirements, which avails applying the array substrate 300 to different types of electronic products.

Moreover, in the fabrication method of the present embodiment, the first block 402 is defined through the back side exposure process, and a pattern thereof is aligned to a pattern of the light shielding device 120. If an alignment error is occurred in the subsequent partial exposure process, the photo spacer 330 is still located in the light shielding region O of the substrate 110 without influencing light transmittance of the light transmitting region T. Therefore, the partial exposure process using the mask M has a higher tolerance for the alignment error, which avails simplifying a whole fabrication flow to shorten the fabrication time.

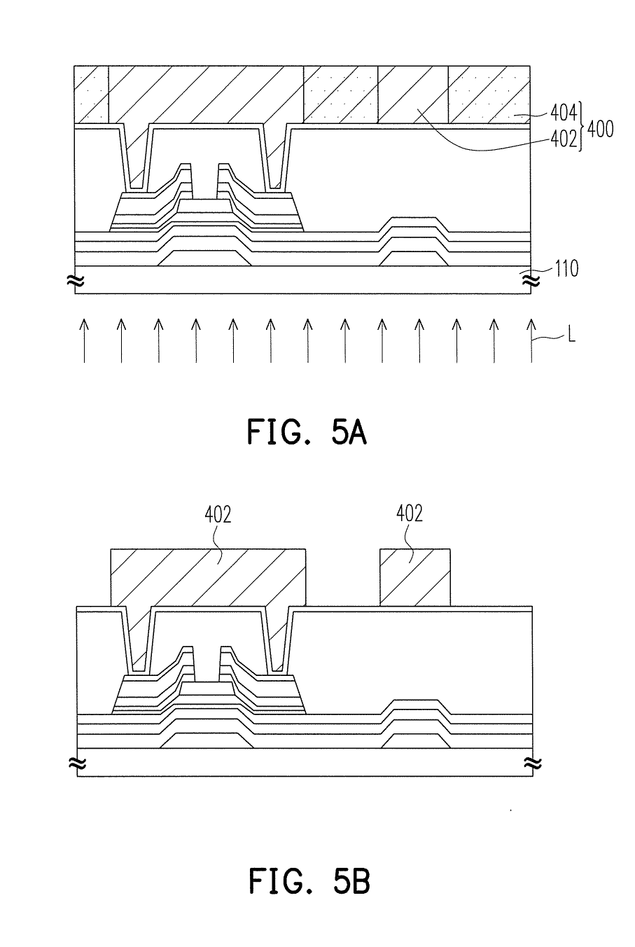

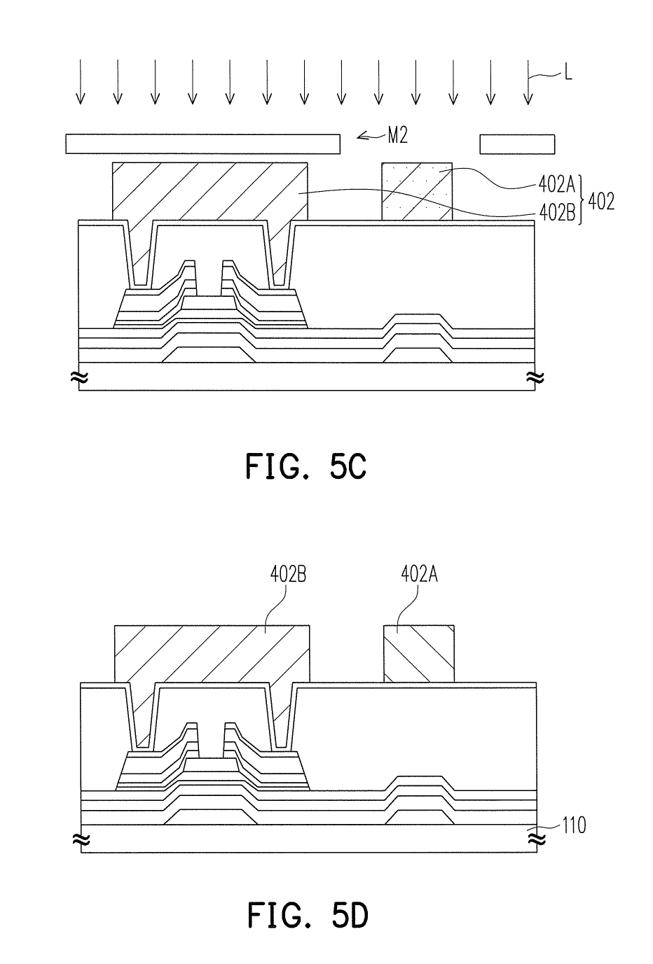

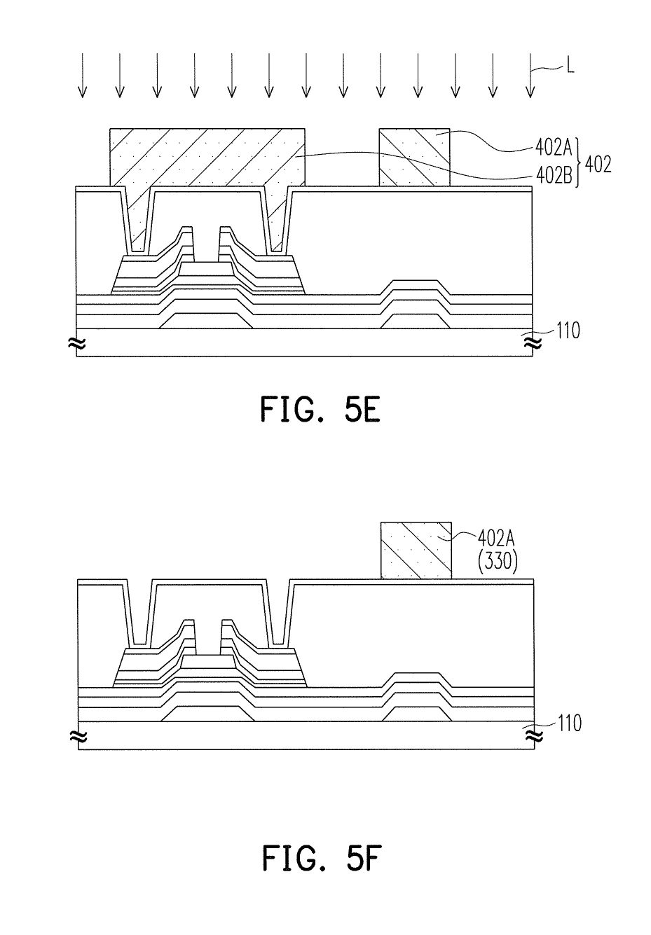

It should be noticed that fabrication of the array substrate of FIG. 3 is not limited to the fabrication method of FIGS. 4A-4F. FIGS. 5A-5F are schematic diagrams illustrating a fabrication method of a photo spacer according to a third embodiment of the disclosure. Referring to FIG. 5A, a back side exposure process is performed and the light L irradiates a photo-sensitive material layer 400 from a side of the substrate 110 apart from the photo-sensitive material layer 400, so as to define a first block 402 and a second block 404 in the photo-sensitive material layer 400. The step of FIG. 5A is substantially the same to the step of FIG. 4A, so that related descriptions of FIG. 4A can be referred.

Since the photo-sensitive material layer 400 is decomposed after exposure, a developing process is performed to remove the exposed second block 404 from the substrate 110. Now, referring to FIG. 5B, the unexposed first block 402 is remained on the substrate 110.

Then, a front side exposure process is performed through the mask M, in which the light L irradiates the substrate 110 from a side of the first block 402 apart from the substrate 110. Here, the mask M has an opening M2 to expose the first sub block 402A of the first block 402, and the second sub block 402B of the first block 402 is shielded by the mask M. In other words, by performing the front side exposure process through the mask M, the first sub block 402A of the first block 402 is exposed, and the second sub block 402B is not exposed.

Then, to obtained the required pattern, as that shown in FIG. 5D, a baking process is performed to cure the exposed first sub block 402A to form a photo spacer. It should be noticed that the second sub block 402B is not exposed before the baking process, so that the second sub block 402B is not cured to form the photo spacer.

Then, referring to FIG. 5E, a full-scale exposure process is performed, and the light L irradiates the whole substrate 110 from a side of the first block 402 apart from the substrate 110. After the full-scale exposure process, the first sub block 402A is maintained to be cured, and the second sub block 402B is decomposed. Therefore, to obtain the required pattern to form the photo spacer 330 shown in FIG. 3, after the full-scale exposure process, a developing process is performed to remove the decomposed second sub block 402B from the substrate 110 to remain the first sub block 402A (shown in FIG. 5F).

In the aforementioned embodiments, a light-sensitive property of the image reversal photoresist lies in that the image reversal photoresist is decomposed after exposure, and is cured after baking while not being exposed to the light. However, the disclosure is not limited thereto, and other embodiments are provided below to describe the method for fabricating the photo spacer by using the photoresist materials of other properties.

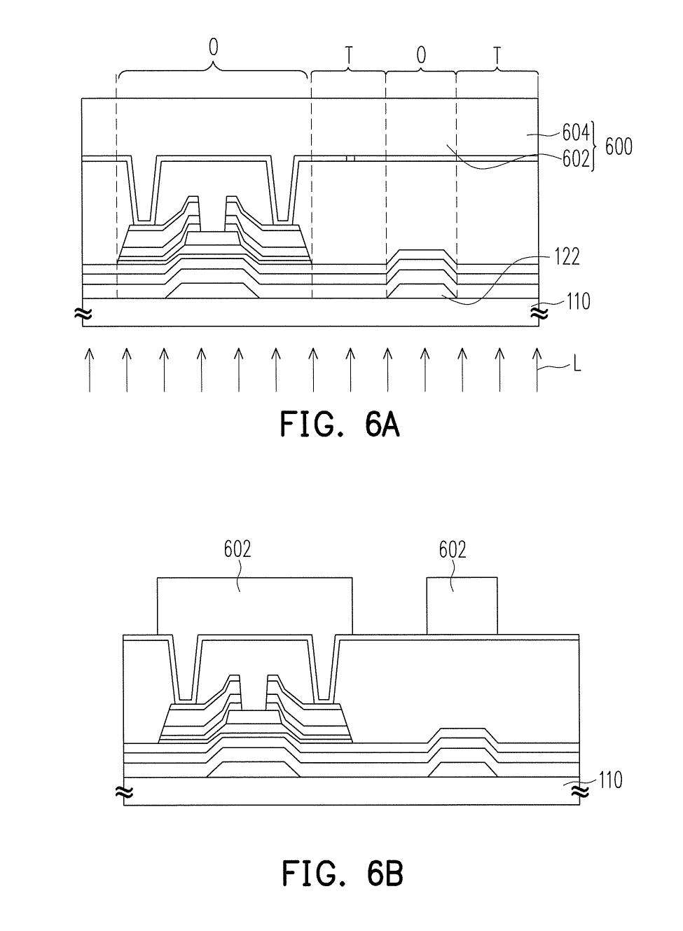

FIGS. 6A-6B are schematic diagrams illustrating a fabrication method of a photo spacer according to a fourth embodiment of the disclosure. Referring to FIG. 6A, a back side exposure process is performed on the substrate 110 formed with a photo-sensitive material layer 600. The substrate 110 has the light transmitting regions T and the light shielding regions O, and during the back side exposure process, the light L cannot pass through the light shielding regions O of the substrate 110. Therefore, the photo-sensitive material layer 600 is defined to have a first block 602 located on the light shielding regions O and the second block 604 located on the light transmitting regions T. In the present embodiment, a material of the photo-sensitive material layer 600 is, for example, a positive photoresist material, so that the second block 504 is decomposed due to exposure.

Then, referring to FIG. 6B, a developing process is performed to remove the exposed second block 604 from the substrate 110, and a coking process is performed to cure the first block 602 on the substrate 110. In the present embodiment, a process temperature of the coking process is from 170° C. to 190° C., or is about 180° C. The first block 602 is indeed cured after the coking process, and is not liable to be deteriorated in subsequent processing steps or utilization process due to light irradiation, so that the photo spacer formed by the first block 602 has ideal reliability.

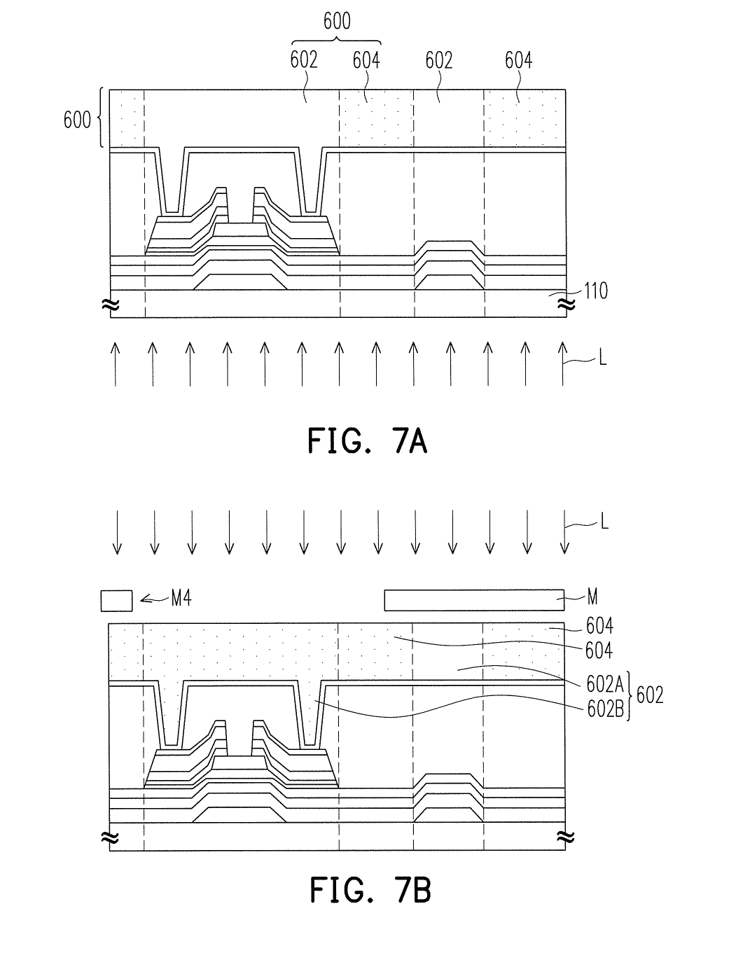

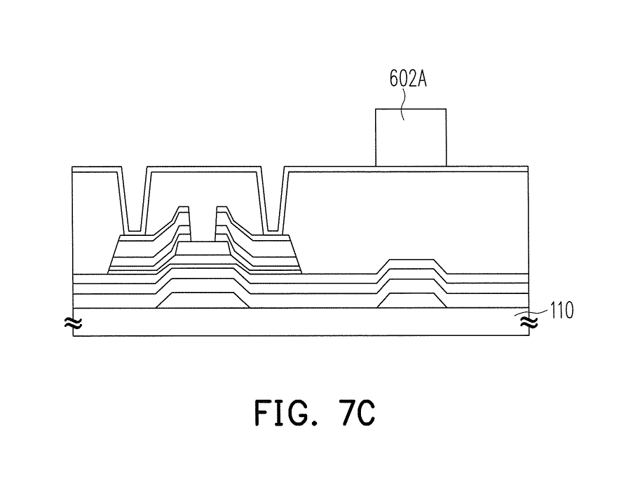

FIGS. 7A-7C are schematic diagrams illustrating a fabrication method of a photo spacer according to a fifth embodiment of the disclosure. Referring to FIG. 7A, similar to the fourth embodiment, a back side exposure process is first performed on the substrate 110 formed with the photo-sensitive material layer 600 to define the first block 602 and the second block 604 in the photo-sensitive material layer 600. A material of the photo-sensitive material layer 600 is, for example, the positive photoresist material, which can be decomposed after exposure. Then, a front side exposure process is performed through the mask M having an opening M4 to define an unexposed first sub block 602A and an exposed second sub block 602B in the first block 602. Now, the second sub block 602B is also in the decomposed state.

Then, a developing process and a coking process (shown in FIG. 7C) are performed to cure and maintain the first sub block 602A on the substrate 110, and the second sub block 602B and the second block 604 in the decomposed state are all removed from the substrate 110 during the developing process. According to the fabrication method of FIGS. 7A-7C, the first block 602 cured on the substrate 110 can be used to form the required photo spacer.

It should be noticed that the photo spacer can be formed on the substrate 110 according to the aforementioned fabrication methods described in the aforementioned embodiments, and the substrate 110 formed with the photo spacer is assembled with another substrate, and a liquid crystal layer is filled there between to form a LCD. Now, the photo spacer fabricated according to the aforementioned fabrication methods can be used to maintain a cell gap of the LCD. Moreover, since the photo spacer can be self-aligned to the light shielding device (for example, the active device array) on the substrate 110 during the fabrication process, configuration of the photo spacer does not negatively influence a display aperture ratio of the LCD.

In summary, during the process of fabricating the photo spacer, the back side exposure process is performed to self-align the pattern formed by the photoresist material layer to the light shielding device on the substrate. Therefore, when the mask is further used to define the required pattern in the follow-up process, the photo spacer is indeed located on the light shielding device regardless of whether the mask is accurately aligned, so that the fabrication method of the disclosure has a higher tolerance for the alignment error of the mask. Meanwhile, when the array substrate having the photo spacer of the disclosure is applied to the LCD, the LCD may have good display quality due to that the photo spacer is not liable to be mis-aligned. Moreover, by using the image reversal photoresist to fabricate the photo spacer, the photo spacer is not liable to be deteriorated in subsequent processing steps or utilization process due to light irradiation. Namely, the photo spacer of the disclosure has ideal reliability.

It will be apparent to those skilled in the art that various modifications and variations can be made to the structure of the disclosure without departing from the scope or spirit of the disclosure. In view of the foregoing, it is intended that the invention cover modifications and variations of this invention provided they fall within the scope of the following claims and their equivalents.

What is claimed is:

1. A method for fabricating a photo spacer, comprising:
forming a photo-sensitive material layer on a substrate, wherein the substrate has at least one light shielding region and at least one light transmitting region, and the photo-sensitive material layer comprises at least one first block located on the at least one light shielding region and at least one second block located on the at least one light transmitting region;
performing a back side exposure process, wherein light irradiates the photo-sensitive material layer from a side of the substrate apart from the photo-sensitive material layer to expose the at least one second block;
performing a developing process to remove the at least one second block from the substrate; and
performing a coking process to cure the at least one first block of the photosensitive material layer into a photo spacer right after the developing process, wherein a process temperature of the coking process is from 170° C. to 190° C.

2. The method for fabricating the photo spacer as claimed in claim 1, wherein the process temperature of the coking process is 180° C.

3. The method for fabricating the photo spacer as claimed in claim 1, wherein before the developing process, a partial exposure process is further performed on the photo-sensitive material layer through a mask, the mask is disposed at a side of the photo-sensitive material layer apart from the substrate to divide the at least one first block into at least one first sub block shielded by the mask and at least one second sub block exposed by the mask, and the at least one second sub block is removed from the substrate through the developing process.
